(19) United States
(12) Patent Application Publication
(10) Pub. No.: US 2006/0203451 A1
(43) Pub. Date: Sep. 14, 2006

(54) Heat dissipation apparatus with second degree curve shape heat pipe

(76) Inventors: Chao-Ke Wei, Taipei Hsien (TW); Heng-Li Chou, San Chung City (TW); Hsiang-Jung Chin, Kaohsiung City (TW); Wen-Liang Hwang, Hsin Chuang City (TW)

Correspondence Address: RABIN & BERDO, P.C., Suite 500, 1101 14 Street, N.W., Washington, DC, 20005, US

(21) Appl. No.: 11/143,605

(22) Filed: Jun. 3, 2005

(30) Foreign Application Priority Data
Mar. 10, 2005 (TW) 94107340

(51) Int. Cl. H05K 7/20

(52) U.S. Cl. 361/700

(57) ABSTRACT

The present invention relates to a heat sink. The heat sink includes a casting, a block, heat pipes, and fins. The block is placed in a cavity of the casting. The heat pipes are composed of a straight heat pipe and two second degree curve heat pipes. The heat pipes are coupled to the casting. The fins are also coupled to the casting. The block absorbs heat from a heat source and transfer to the fins via heat pipes for heat dissipation.

### RELATED APPLICATIONS

The present application is based on, and claims priority from, Taiwan Application Serial Number 94107340, filed Mar. 10, 2005, the disclosure of which is hereby incorporated by reference herein in its entirety.

### BACKGROUND OF THE INVENTION

1. Field of Invention

The invention relates to a heat dissipation apparatus and, in particular, to a heat apparatus with a second degree curve shape heat pipe.

2. Related Art

With the rapid development in information technology, computers have a lot of applications because of their ability to processing huge amounts of digital data. Due to improvement in the manufacturing process of integrated circuits (IC), there are higher demands on the functional specifications of the IC's. Currently, the IC design becomes very complicated and subtle.

Take the central processing unit (CPU) as an example, users and various applications rely very much on it. Therefore, its circuit layout is much more complicated than before. Although these CPU IC chips provide many powerful functions, there are new problems generated. For example, the complicated circuit consumes a lot of electrical energy which will result in temperature rise on the chip. This is a serous problem. Generally speaking, it is very important to rapidly remove heat in order for the computer to reach its largest efficiency. If heat is accumulated inside the computer without being dissipated, the electronic elements cannot function normally and may even damage the whole system.

A conventional computer heat sink for a high power CPU can be a heat sink directly installed on the CPU. A fan directs airflow toward the heat dissipation fins on the CPU. To effectively guide the heat generated by the CPU out of the computer, one often uses heat pipes and fins to guide the heat generated by the CPU and the airflow produced by a fan to remove the heat.

However, as the speeds of computer systems increase, the heat generated by the CPU gets higher and the required volume of the heat sink also gets larger in order to remove the heat. Therefore, how to further increase the efficiency of the heat sink and, in particular, that of the heat pipes and fins is the goal of computer manufacturers.

### SUMMARY OF THE INVENTION

An object of the invention is to provide a heat apparatus with a second degree curve shape heat pipe to efficiently transfer the heat produced by the source.

The disclosed heat apparatus with a second degree curve shape heat pipe contains a casting, a block, a plurality of heat pipes and a plurality of fins. The block is placed in a cavity of the casting. The heat pipes are composed of a straight heat pipe and two second degree curve heat pipes. The heat pipes are coupled to the casting. The fins are also coupled to the casting. The block absorbs heat from a heat source and transfer to the fins via heat pipes for heat dissipation.

### BRIEF DESCRIPTION OF THE DRAWINGS

These and other features, aspects and advantages of the invention will become apparent by reference to the following description and accompanying drawings which are given by way of illustration only, and thus are not limitative of the invention, and wherein:

FIG. 1A is an assembly diagram of the heat apparatus with a second degree curve shape heat pipe according to a preferred embodiment of the invention;

FIG. 1B is a disassembly diagram of the heat apparatus with a second degree curve shape heat pipe according to a preferred embodiment of the invention;

FIG. 2A is a top view of the casting and heat pipe in the first embodiment;

FIG. 2B is another top view of the casting and heat pipe in the first embodiment;

FIG. 3A is a cross-sectional side view of the heat apparatus with a second degree curve shape heat pipe according to a preferred embodiment of the invention; and

FIG. 3B is another cross-sectional side view of the heat apparatus with a second degree curve shape heat pipe according to a preferred embodiment of the invention.

### DETAILED DESCRIPTION OF THE PREFERRED EMBODIMENT

The disclosed heat apparatus with a second degree curve shape heat pipe has a straight heat pipe and two second degree curve heat pipes. The heat pipe is disposed at the bottom of the heat pipe and fins heat sink, and the two second degree curve heat pipes are disposed in a symmetric way with respect to the heat pipe. A better heat exchange efficiency is achieved using the high thermal conductivity of the heat pipe.

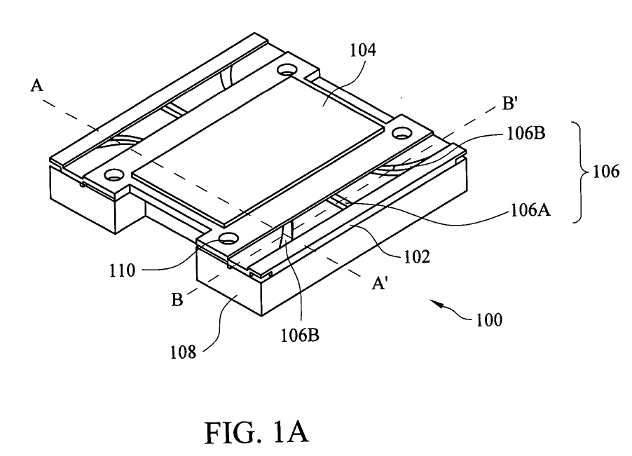

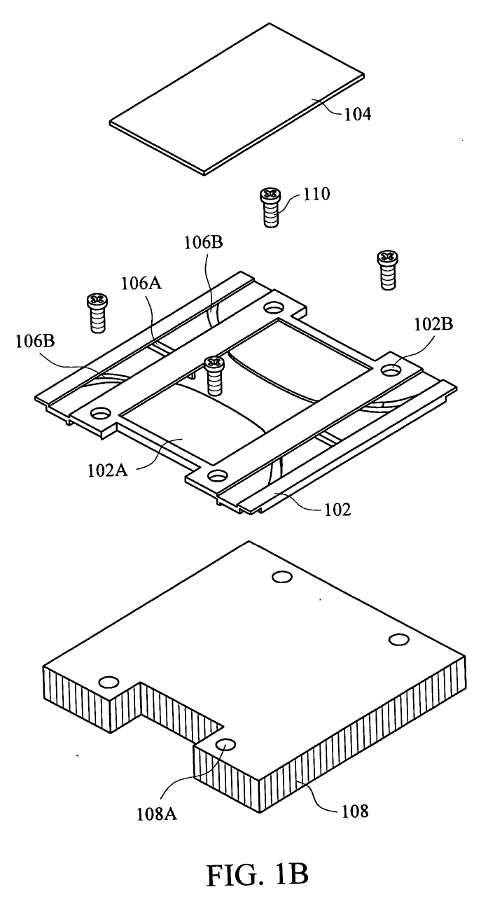

FIGS. 1A and 1B show the assembled and disassembled three-dimensional views of the heat apparatus with a second degree curve shape heat pipe 100 according to a preferred embodiment of the invention. The heat apparatus 100 contains a casting 102, a block 104, a heat pipe 106, and fins 108. The block 104 can be fixed by, for example, soldering on a top surface with a cavity 102A of the casting 102. The bottom of the casting 102 is disposed with the heat pipe 106. The heat pipe 106 includes a straight heat pipe 106A and two second degree curve heat pipes 106B. The straight heat pipe 106A is disposed in the middle of the heat pipe 106, and the two second degree curve heat pipes 106B are disposed in a symmetric way respect to the straight heat pipe 106A. They can be coupled to the casting 102 by soldering. The fins 108 are aligned in parallel to form a fin array. They are fixed on the bottom surface of the casting 102 using fixing elements 110, such as screws and screw holes 102B, 108A.

When in use, the heat apparatus with a second degree curve shape heat pipe 100 is installed on a heat source, such as a CPU, for heat dissipation. It is in contact with the heat source via the block 104. The heat generated by the heat source is absorbed by the block 104 and transferred via the heat pipe 106 to the fins 108. In the end, the heat is dissipated into the environment.

The casting 102, the block 104, and the heat pipe 106 can be made of metals with high thermal conduction coefficients, e.g. copper (Cu) or aluminum (Al). The casting 102 is preferably made of aluminum. The block 104 and the heat pipe 106 are preferably made of copper.

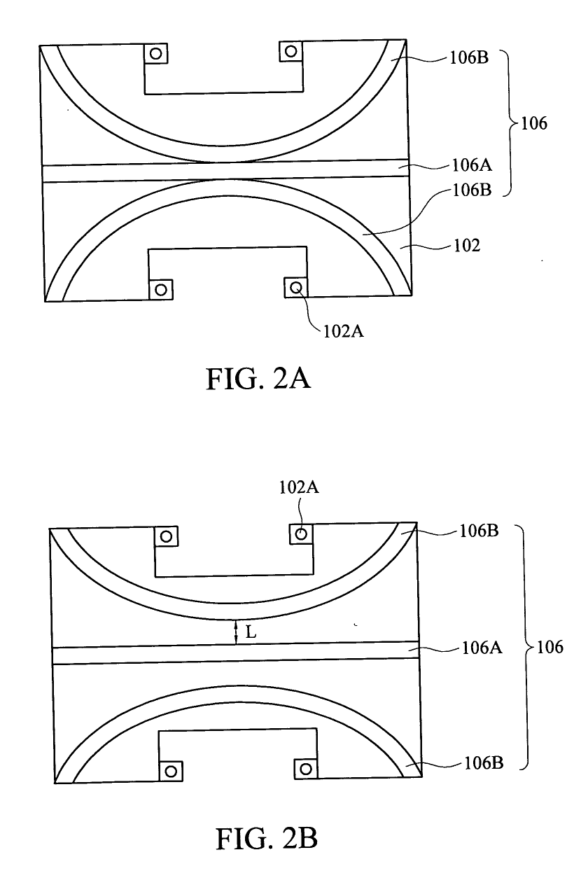

FIGS. 2A and 2B are top views of the casting 102 and the heat pipe 106, explaining how the heat pipe 106 is installed on the casting 102. As shown in FIG. 2A, the straight heat pipe 106A and the second degree curve heat pipes 106B are disposed at the bottom of the casting 102. The straight heat pipe 106A is disposed in the middle of the heat pipe 106, and the two second degree curve heat pipes 106B are disposed in a symmetric way respect to the straight heat pipe 106A. This configuration can be appropriately adjusted according to the position of the heat source. For example, if the heat generated by the heat source mostly concentrates in the middle part of the casting 102, the straight heat pipe 106A and the two second degree curve heat pipes 106B can be disposed as shown in FIG. 2A to enhance the heat exchange between the heat pipe 106 and the heat source. If the heat generated by the heat source covers a wider range, then one may adopt the configuration in FIG. 2B where the straight heat pipe 106A and the two second degree curve heat pipes 106B are distributed evenly on the casting 102. For example, a minimum distance L is kept between the straight heat pipe 106A and the two second degree curve heat pipes 106B.

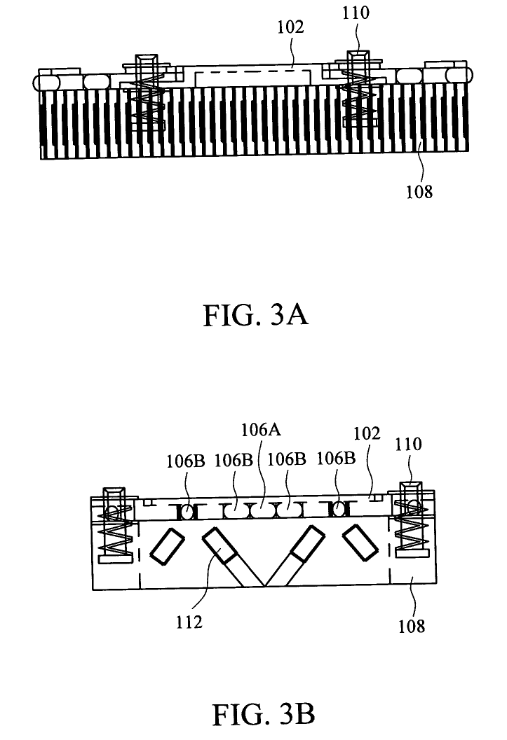

FIGS. 3A and 3B are cross-sectional side views of the heat apparatus with a second degree curve shape heat pipe 100. FIG. 3A is the cross-sectional view of FIG. 1A along the A-A′ cutting line, showing how the fins 108 are coupled to the casting 102. As shown in the drawing, the fins 108 are disposed in parallel to form a fin array. They are coupled together by, for example, soldering. They are then coupled to the casting 102 using fixing elements such as screws.

FIG. 3B is the cross-sectional view of FIG. 1 along the B-B′ cutting line. As shown in the drawing, the fin array formed from the fins 108 has many hollow channels 112 to increase the overall heat dissipation efficiency of the fins 108.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A heat apparatus, comprising:
a casting with a top surface and a bottom surface;
a block, coupled to the top surface of the casting;
a plurality of heat pipes, including a straight heat pipe and two second degree curve heat pipes, all coupled to the bottom surface of the casting; and
a plurality of fins, coupled to the bottom surface of the casting;
wherein the block absorbs heat from a heat source and transfers to the fins via the heat pipes for heat dissipation.

2. The heat apparatus of claim 1, wherein the straight heat pipe and the two second degree curve heat pipes are disposed in such a way that the straight heat pipe is in the middle and the two second degree curve heat pipes are positioned in a symmetric way with respect to the straight heat pipe.

3. The heat apparatus of claim 1, wherein the casting is made of a metal of a high thermal conduction coefficient.

4. The heat apparatus of claim 3, wherein the casting is made of aluminum.

5. The heat apparatus of claim 1, wherein the block is made of a metal of a high thermal conduction coefficient.

6. The heat apparatus of claim 5, wherein the block is made of copper.

7. The heat apparatus of claim 1, wherein the heat pipes are made of metals of high thermal conduction coefficients.

8. The heat apparatus of claim 7, wherein the heat pipes are made of copper.

9. The heat apparatus of claim 1, wherein the fins are coupled to the casting by at least one fixing element.

10. The heat apparatus of claim 9, wherein the fixing element is a screw.

11. The heat apparatus of claim 1, wherein the heat pipes are coupled to the casting by soldering.

12. The heat apparatus of claim 1, wherein the block is coupled to the casting by soldering.

13. The heat apparatus of claim 1, wherein the fins are disposed in parallel to form a fin array.

14. The heat apparatus of claim 1, wherein the block is coupled to a cavity of the casting.

15. A heat apparatus with a second degree curve shape heat pipe, comprising:
a casting with a top surface and a bottom surface;
a block, coupled to a cavity on the top surface of the casting;
a plurality of heat pipes, including a straight heat pipe and two second degree curve heat pipes, all coupled to the bottom surface of the casting with the straight heat pipe disposed in the middle and the two second degree curve heat pipes disposed symmetrically on opposite sides of the straight heat pipe; and
a plurality of fins, disposed in parallel to form a fin array and coupled to the bottom surface of the casting;
wherein the block absorbs heat from a heat source transfer to the fins via the heat pipes for heat dissipation.

16. The heat apparatus with a second degree curve shape heat pipe of claim 15, wherein the casting is made of a metal of a high thermal conduction coefficient.

17. The heat apparatus with a second degree curve shape heat pipe of claim 16, wherein the casting is made of aluminum.

18. The heat apparatus with a second degree curve shape heat pipe of claim 15, wherein the block is made of a metal of a high thermal conduction coefficient.

19. The heat apparatus with a second degree curve shape heat pipe of claim 18, wherein the block is made of copper.

20. The heat apparatus with a second degree curve shape heat pipe of claim 15, wherein the heat pipes are made of metals of high thermal conduction coefficients.

21. The heat apparatus with a second degree curve shape heat pipe of claim 20, wherein the heat pipes are made of copper.

22. The heat apparatus with a second degree curve shape heat pipe of claim 15, wherein the fins are coupled to the casting by at least one fixing element.

23. The heat apparatus with a second degree curve shape heat pipe of claim 22, wherein the fixing element is a screw.

24. The heat apparatus with a second degree curve shape heat pipe of claim 15, wherein the heat pipes are coupled to the casting by soldering.

25. The heat apparatus with a second degree curve shape heat pipe of claim 15, wherein the block is coupled to the casting by soldering.
